(19) United States
(12) Patent Application Publication
(10) Pub. No.: US 2026/0351331 A1
(43) Pub. Date: Nov. 5, 2026

(54) BLOCK FAMILY ERROR HANDLING AVOIDANCE IN A MEMORY DEVICE USING OPTIMAL READ VOLTAGE OFFSETS

(71) Applicant: MICRON TECHNOLOGY, INC., Boise, ID (US)

(72) Inventors: Shantilal Rayshi Doru, San Diego, CA (US); Jun Wan, San Jose, CA (US); Steven Michael Kientz, Westminster, CO (US); Patrick R. Khayat, San Diego, CA (US); Zixiang Loh, San Jose, CA (US)

(21) Appl. No.: 19/195,003

(22) Filed: Apr. 30, 2025

(51) Int. Cl. G11C 29/52; G11C 16/08; G11C 16/26; G11C 16/34

(52) U.S. Cl. CPC G11C 29/52; G11C 16/08; G11C 16/26; G11C 16/3404

(57) ABSTRACT

A request to perform a read operation on a target page is received. Whether an entry of an error handling data structure includes a block address of the target page is determined. A first set of optimal read voltage offset values for a previously failed page associated with the block address is obtained from the first entry of the error handling data structure responsive to determining that a first entry of the error handling data structure includes the block address of the target page. The read operation is performed on the target page based on the first set of optimal read voltage offset values for the previously failed page associated with the block address.

### TECHNICAL FIELD

Embodiments of the disclosure are generally related to memory sub-systems, and more specifically, are related to block family error handling avoidance in a memory device using optimal read voltage offsets.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of some embodiments of the disclosure.

FIG. 1 illustrates an example computing system that includes a memory sub-system in accordance with some embodiments of the present disclosure.

FIG. 2 depicts an example graph illustrating the dependency of the threshold voltage offset on the time after program (i.e., the period of time elapsed since the block had been programmed), in accordance with some embodiments of the present disclosure.

FIG. 3 schematically illustrates a set of predefined threshold voltage offset bins, in accordance with embodiments of the present disclosure.

FIG. 4 schematically illustrates selecting block families for calibration, in accordance with embodiments of the present disclosure.

FIG. 5 illustrates an example block family error avoidance (BFEA) data structure maintained by the memory sub-system controller for read level management on a memory device using block family error avoidance, in accordance with embodiments of the present disclosure.

FIG. 6 illustrates an example error handling data structure wordline group offset data structure maintained by the memory sub-system controller for block family error handling avoidance using optimal read voltage offsets, in accordance with embodiments of the present disclosure.

FIG. 7 illustrates an example wordline group offset data structure maintained by the memory sub-system controller for block family error handling avoidance using optimal read voltage offsets, in accordance with embodiments of the present disclosure.

FIG. 8 is a flow diagram of an example method of block family error handling avoidance using optimal read voltage offsets, in accordance with some embodiments of the present disclosure.

FIG. 9 is a block diagram of an example computer system in which embodiments of the present disclosure may operate.

### DETAILED DESCRIPTION

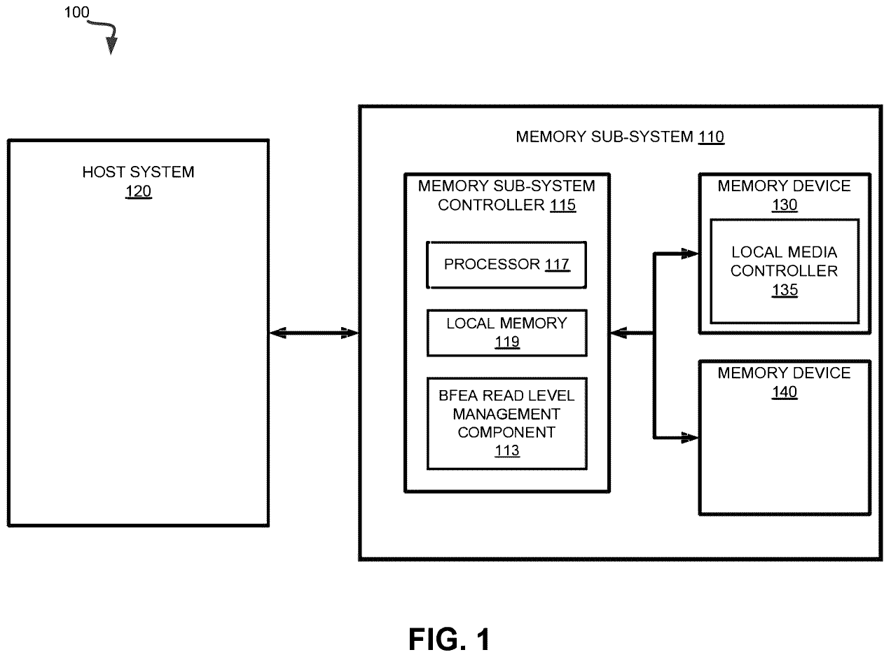

Aspects of the present disclosure are directed to block family error avoidance (BFEA) in a memory device using optimal read voltage offsets. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIG. 1. A non-volatile memory device is a package of one or more dies. Each die can include two or more planes, such that each plane carries a matrix of memory cells formed onto a silicon wafer and joined by conductors referred to as wordlines and bitlines, such that a wordline joins multiple memory cells forming a row of the matric of memory cells, while a bitline joins multiple memory cells forming a column of the matric of memory cells. Depending on the cell type, each memory cell can store one or more bits of binary information, and has various logic states that correlate to the number of bits being stored. The logic states can be represented by binary values, such as “0” and “1”, or combinations of such values. A set of memory cells referred to as a memory page can be programmed together in a single operation, e.g., by selecting consecutive bitlines.

Data operations can be performed by the memory sub-system. The data operations can be host-initiated operations. For example, the host system can initiate a data operation (e.g., write, read, erase, etc.) on a memory sub-system. The host system can send access requests (e.g., write command, read command) to the memory sub-system, such as to store data on a memory device at the memory sub-system and to read data from the memory device on the memory sub-system. The data to be read or written, as specified by a host request, is hereinafter referred to as “host data.” A host request can include logical address information (e.g., logical block address (LBA), namespace) for the host data, which is the location the host system associates with the host data. The logical address information (e.g., LBA, namespace) can be part of metadata for the host data. Metadata can also include error handling data (e.g., ECC codeword, parity code), data version (e.g. used to distinguish age of data written), valid bitmap (which LBAs or logical transfer units contain valid data), etc.

A memory device includes multiple memory cells, each of which can store, depending on the memory cell type, one or more bits of information. A memory cell can be programmed (written to) by applying a certain voltage to the memory cell, which results in an electric charge being held by the memory cell, thus allowing modulation of the voltage distributions produced by the memory cell. Moreover, precisely controlling the amount of the electric charge stored by the memory cell allows to establish multiple threshold voltage levels corresponding to different logical levels, thus effectively allowing a single memory cell to store multiple bits of information: a memory cell operated with 2n different threshold voltage levels is capable of storing n bits of information. Thus, the read operation can be performed by comparing the measured voltage exhibited by the memory cell to one or more reference voltage levels in order to distinguish between two logical levels for single-level cells and between multiple logical levels for multi-level cells.

Due to the phenomenon known as slow charge loss (SCL), the threshold voltage of a memory cell changes in time as the electric charge of the cell is degrading, which is referred to as “temporal voltage shift” (since the degrading electric charge causes the voltage distributions to shift along the voltage axis towards lower voltage levels). The threshold voltage is changing rapidly at first (immediately after the memory cell was programmed), and then slows down in an approximately logarithmic linear fashion with respect to the time elapsed since the cell programming event. Accordingly, failure to mitigate the temporal voltage shift caused by the slow charge loss can result in the increased bit error rate in read operations.

Some memory sub-systems mitigate the temporal voltage shift by employing block family based error avoidance strategies. The temporal voltage shift is selectively tracked for programmed blocks grouped by block families, and appropriate voltage offsets, which are based on block affiliation with a certain block family, are applied to the base read levels in order to perform read operations. “Block family” herein shall refer to a set of blocks that have been programmed within a specified time window and a specified temperature window. Since the time elapsed after programming and temperature are the main factors affecting the temporal voltage shift, all blocks and/or partitions within a single block family are presumed to exhibit similar distributions of threshold voltages in memory cells, and thus would require the same voltage offsets to be applied to the base read levels for read operations. “Base read level” herein shall refer to the initial threshold voltage level exhibited by the memory cell immediately after programming. In some implementations, base read levels may be stored in the metadata of the memory device.

Block families can be created asynchronously with respect to block programming events. In an illustrative example, a new block family can be created whenever a specified period of time (e.g., a predetermined number of minutes) has elapsed since creation of the last block family or the reference temperature of memory cells has changed by more than a specified threshold value. The memory sub-system controller can maintain an identifier of the active block family, which is associated with one or more blocks as they are being programmed.

The memory sub-system controller can periodically perform a calibration process (also referred to as a calibration scan) in order to evaluate a data state metric (e.g., a bit error rate) and associate each block family with one of predefined threshold voltage offset bins (referred to as bins), which is in turn associated with the voltage offset to be applied for read operations. The bins can be numbered from 0 to 7 (e.g., bin 0-bin 7), and each bin can be associated with a voltage offset to be applied to base read levels for read operations. The associations of block families with bins (e.g., bins 0-7) can be stored in respective metadata tables maintained by the memory sub-system controller. However, in between the periodic calibration, memory cells over time can experience increased numbers of program erase cycles (PECs), read counts (e.g., read disturb), and data retention. As a result, the initial threshold voltage with the corresponding voltage offset of the memory cell associated with a block family may no longer be accurate to read data from the memory cell. Accordingly, failure to mitigate the effects of PECs, read disturbs, and data retention, which can result in an increased bit error rate in, read operations. The increased bit error rates may subsequently result in a read error.

“Read error” refers to a memory sub-system's failure to validate one or more data items that have been retrieved from a memory device in response to a read command. Read errors can be associated with host-initiated read operations or system-initiated scanning operations and can occur due to, for example, the measured threshold voltage VT exhibited by the memory cell mismatching the read voltage levels due to TVS, the requested data being subjected to noise or interference, etc. In a read error, the number of bit errors in the read data is greater than what the underlying ECC can correct which results in an ECC failure. In response to a read error, the memory sub-system can perform an error-handling flow in an attempt to recover the data. The error-handling flow can include one or more error-handling operations performed with respect to the data items that have been retrieved from the memory device. An error handling operation, for example, can include one or more read retries using different parameters, such as read voltages, as compared to the initial read operation performed on the memory cell. The read voltage that is used to successfully read data from the memory cell may be considered the optimal read voltage.

Furthermore, since the same voltage offset is applied to the initial threshold voltage for memory cells associated with the same block family, other memory cells of the same block family may experience similar increased bit error rates. In most instances, since the previous read of a memory cell of the same block family resulted in a read error triggering the error-handling flow, a subsequent read of another memory cell within the same block family may result in another read error triggering the error-handling flow. However, performing the error-handling flow on memory cells of the same block family for every read of a memory cell in the same block family can be time consuming and contribute to increased latency in performing memory access operations on the memory device.

Aspects of the present disclosure address the above-noted and other deficiencies by performing a read operation on a target page using a plurality optimal read voltage offset values for a previously failed page belonging to a block of the target page. In particular, a memory sub-system controller maintains a BFEA data structure, an error handling data structure, and/or a wordline (WLG) data structure.

The BFEA data structure, for each time after program (TAP) bin of the predetermined number of TAP bins, an entry which include a plurality of default voltage offset values to be applied to base read levels for read operations. Each default voltage offset value refers to an offset value applied to a base read level at one of the threshold voltage levels (e.g., L1-L7). The error handling data structure includes an entry for each page that underwent error handling (e.g., previously failed pages) which includes a block address of the previously failed page, a WLG of the previously failed page, and a plurality of optimal read voltage offset values for the previously failed page. Each optimal read voltage offset value corresponds to a threshold voltage level (e.g., L1-L7). The WLG data structure includes an entry for each WLG of the memory device which includes a plurality of WLG offset values. Each WLG offset value corresponds to a threshold voltage level (e.g., L1-L7).

In response to receiving a request to perform a read operation on the target page, the memory sub-system controller determines whether an entry of the error handling data structure includes a block address of the target page. If an entry of the error handling data structure includes the block address of the target page, the memory sub-system controller determines a plurality of delta WLG offset values. The memory sub-system controller determines the plurality of delta WLG offset values by calculating a difference between a plurality of WLG offset values for a WLG of the previously failed page and a plurality of WLG offset values for a WLG of the target page. Using the plurality of optimal read voltage offset values and the plurality of delta WLG offset values, the memory sub-system controller calculates a plurality of threshold offset values. In particular, the plurality of threshold offset values is a sum of the plurality of optimal read voltage offset values and the plurality of delta WLG offset values. Accordingly, the memory sub-system controller performs a read operation using the plurality of threshold offset values. The plurality of threshold offset values is added to the base read levels to read the data from the target page.

If the read operation fails, the memory sub-system controller performs an error handling operation on the target page and obtains a plurality of current optimal read voltage offset values for the target page. The memory sub-system controller replaces the plurality of optimal read voltage offset values and the WLG of the entry (associated with the previously failed page) with the plurality of optimal read voltage offset values and the WLG for the target page.

If an entry of the error handling data structure does not include the block address of the target page, the memory sub-system controller obtains a plurality of default voltage offset values from the BFEA data structure. The memory sub-system controller performs a read operation on the target page using the plurality of default voltage offset values. The plurality of default voltage offset values is added to the base read levels to read the data from the target page. If the read operation fails, the memory sub-system performs an error handling operation on the target page to obtain a plurality of optimal read voltage offset values. As a result, an entry is included in the error handling data structure, the entry include a block address of the target page, a WLG of the target page, and the plurality of optimal read voltage offset values for the target page.

Advantages of the present disclosure include, but are not limited to, improving the performance of read operations and decrease the amount of media management operations (e.g., read calibration, media scan, or read retry), thereby improving latency of the memory device.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks. Some types of memory, such as 3D cross-point, can group pages across dice and channels to form management units (MUs).

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical MU address, physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a block family error avoidance (BFEA) read level management component 113 that can perform read operations on a set of memory cells (e.g., a target page) using an error handling data structure and a WLG data structure to adjust base read levels for the target page belonging to a block associated with a page that underwent error handling. In some embodiments, the memory sub-system controller 115 includes at least a portion of the BFEA read level management component 113. In some embodiments, the BFEA read level management component 113 is part of the host system 110, an application, or an operating system. In other embodiments, local media controller 135 includes at least a portion of BFEA read level management component 113 and is configured to perform the functionality described herein.

The BFEA read level management component 113 may store a BFEA data structure, an error handling data structure, and a WLG data structure in the local memory 119 of the memory sub-system controller 115.

The BFEA data structure may include an entry for each time-after-programming (TAP) bin of the predetermined number of TAP bins, similar to the bins (e.g., bins 0-7) previously discussed. Each entry (e.g., TAP bin) may include a plurality of default voltage offset values to be applied to base read levels for read operations. In particular, each default voltage offset value of the plurality of default voltage offset values refers to an offset value applied to a base read level at one of the threshold voltage levels (e.g., L1-L7). For example, a first default voltage offset value of the plurality of default voltage offset values is applied to a first base read level of the base read levels. The associations of block families with TAP bins (e.g., bins 0-7) can be stored in respective metadata tables maintained by the memory sub-system controller. Accordingly, the association of a set of memory cells with a block family and that block family's association with a TAP bin, a corresponding plurality of default voltage offset values obtained from the BFEA data structure referenced by the TAP bin is applied to the base read levels.

The error handling data structure may include an entry for each block associated with a page that underwent error handling (e.g., a previously failed page). Each entry may include a block address of a previously failed page, a WLG of the previously failed page, and a plurality of optimal read voltage offset values for the previously failed page. Block address indicates a die and block that together specify a physical block location in the memory device. WLG refers to a set of adjacent wordlines containing the page and other pages that share common operational characteristics due to their proximity. The plurality of optimal read voltage offset values for the previously failed page is determined through iterative adjustments of read reference voltages during error handling operations. Each optimal read voltage offset value represents a specific voltage adjustment that enables successful reading of the data of the previously failed page. Each optimal read voltage offset value of the plurality of optimal read voltage offset values corresponds to a threshold voltage level (e.g., L1-L7). In some embodiments, the error handling data structure limits a number of entries for each block to a first occurrence of a previously failed page associated with a respective block.

The WLG data structure may include an entry for each WLG of the memory device (e.g., memory device 130 and/or 140). Each entry includes a WLG and a plurality of WLG offset values. The plurality of WLG offset values for a WLG represents a differences between a plurality of WLG offset values of the WLG and a plurality of WLG offset values of a WLG designated as a reference WLG. Each WLG offset value of the plurality of WLG offset values is predefined value generated during manufacturing based on characteristics of the WLG. Each WLG offset value of the plurality of WLG offset values corresponds to a threshold voltage level (e.g., L1-L7). In some embodiments, each entry may include, instead of the plurality of WLG offset values, a slope and intercept that represent the plurality of WLG offset values for a respective entry.

The BFEA read level management component 113 may receive a request to perform a read operation on a page (e.g., a target page). The BFEA read level management component 113 determines a block address of the target page. The BFEA read level management component 113 determines whether the error handling data structure includes an entry for the block address of the target page.

In response to determining that the error handling data structure includes an entry for the block address of the target page, the BFEA read level management component 113 obtains, from the entry of the error handling data structure that includes the block address of the target page, a plurality of optimal read voltage offset values (i.e., the plurality of optimal read voltage offset values of the previously failed page) and a WLG (i.e., the WLG of the previously failed page).

The BFEA read level management component 113 obtains, using a WLG of the target page, a plurality of WLG offset values for the target page. The BFEA read level management component 113 obtains, using the WLG of the previously failed page, a plurality of WLG offset values for the previously failed page. The BFEA read level management component 113 calculates, using plurality of WLG offset values for the target failed page and the plurality of WLG offset values for the previously failed page, a plurality of delta WLG offset values. The plurality of delta WLG offset values is calculated by subtracting the plurality of WLG offset values for the previously failed page from the plurality of WLG offset values for the previously failed page.

The BFEA read level management component 113 calculates, using the plurality of optimal read voltage offset values and the plurality of delta WLG offset values, a plurality of threshold offset values. The plurality of threshold offset values is calculated by adding the plurality of optimal read voltage offset values and the plurality of delta WLG offset values. The BFEA read level management component 113 performs, using the plurality of threshold offset values, a read operation on the target page. In particular, the BFEA read level management component 113 adds the plurality of threshold offset values to the base read levels to read the data from the target page. For example, at each threshold voltage of the plurality of threshold voltages (e.g., L0-L7), a sum of a threshold offset value of the plurality of threshold offset values and a base read level of the base read levels is obtained to read the data from the target page.

In some embodiments, the read operation performed on the target page using the plurality of threshold offset values may fail. The BFEA read level management component 113, as a result, performs an error handling operation on the target page and obtains a plurality of optimal read voltage offset values. As previously described, the error handling operation can include one or more read retries using different parameters, such as read voltages, as compared to the initial read operation performed on the memory cell. The BFEA read level management component 113 may replace the entry of the error handling data structure for the previously failed page with an entry of the error handling data structure for the target page. For example, the BFEA read level management component 113 may replace, in the entry of the error handling data structure for the previously failed page, the plurality of optimal read voltage offset values and the WLG for the previously failed page is replaced with the plurality of optimal read voltage offset values and the WLG for the target page. In some embodiments, the block address of the entry of the error handling data structure may remain unchanged since the block address for the previously failed page matches the block address of the target page.

In response to determining that the error handling data structure does not include an entry for the block address of the target page, the BFEA read level management component 113 may obtain a plurality of default voltage offset values referenced by the TAP bin in view of the association of the block with the block family, and subsequently the association of the block family to the TAP bin. The BFEA read level management component 113 may perform the read operation on the target page by adding the plurality of default voltage offset values to the base read levels to read the data from the target page.

In some embodiments, the read operation using the plurality of default voltage offset values may fail. The BFEA read level management component 113, as a result, performs error handling operation on the target page to obtain a plurality of optimal read voltage offset values. The BFEA read level management component 113 may include, in the error handling data structure, an entry for the target page which includes a block address, a WLG, and the plurality of optimal read voltage offset values of the target page. The entry is included in the error handling data structure since there is no entry for the block address of the target page.

In some embodiments, a block of a block family association with a TAP bin may have transitioned to another TAP bin. As a result, the BFEA read level management component 113 identifies an entry of the error handling data structure that includes a block address of the block and removes the entry from the error handling data structure.

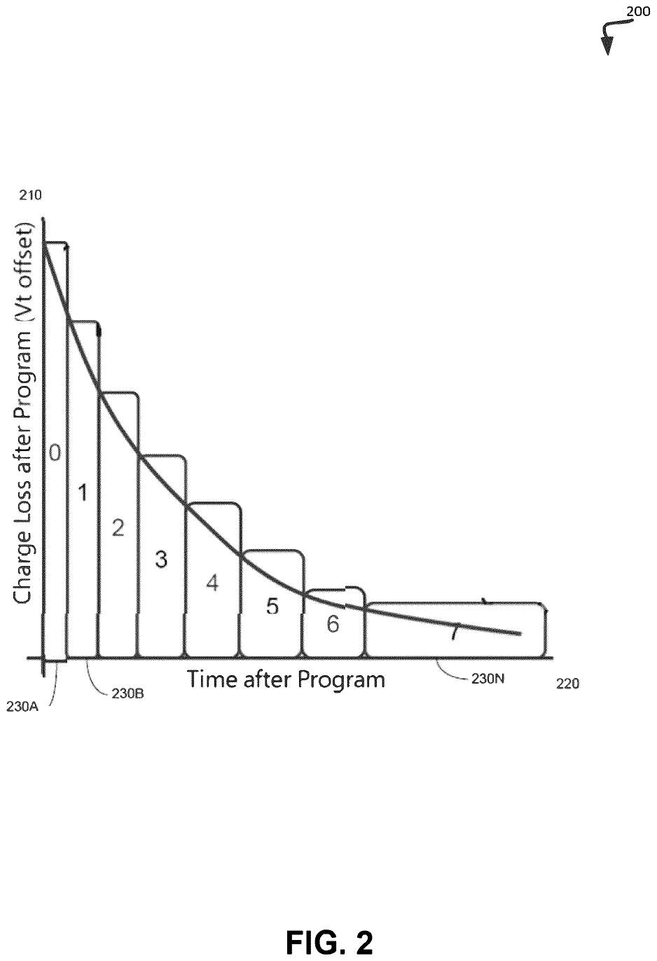

FIG. 2 depicts an example graph 200 illustrating the dependency of the threshold voltage offset 210 on the time after program 220 (i.e., the period of time elapsed since the block had been programmed). As schematically illustrated by FIG. 2, blocks of the memory device are grouped into block families 230A-230N, such that each block family includes one or more blocks that have been programmed within a specified time window and a specified temperature window. As noted herein above, since the time elapsed after programming and temperature are the main factors affecting the temporal voltage shift, all blocks and/or partitions within a single block family 210 are presumed to exhibit similar distributions of threshold voltages in memory cells, and thus would require the same voltage offsets for read operations.

Block families can be created asynchronously with respect to block programming events. In an illustrative example, the memory sub-system controller 115 of FIG. 1 can create a new block family whenever a specified period of time (e.g., a predetermined number of minutes) has elapsed since creation of the last block family or whenever the reference temperature of memory cells, which is updated at specified time intervals, has changed by more than a specified threshold value since creation of the current block family.

A newly created block family can be associated with bin 0. Then, the memory sub-system controller can periodically perform a calibration process in order to associate each die of every block family with one of the predefines threshold voltage offset bins (bins 0-7 in the illustrative example of FIG. 2), which is in turn associated with the voltage offset to be applied for read operations. The associations of blocks with block families and block families and dies with threshold voltage offset bins can be stored in respective metadata tables maintained by the memory sub-system controller.

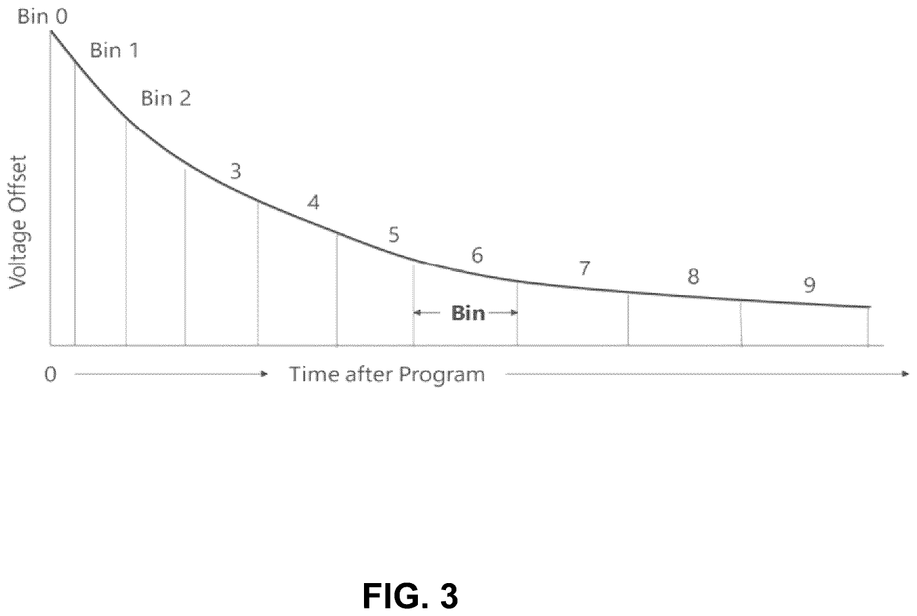

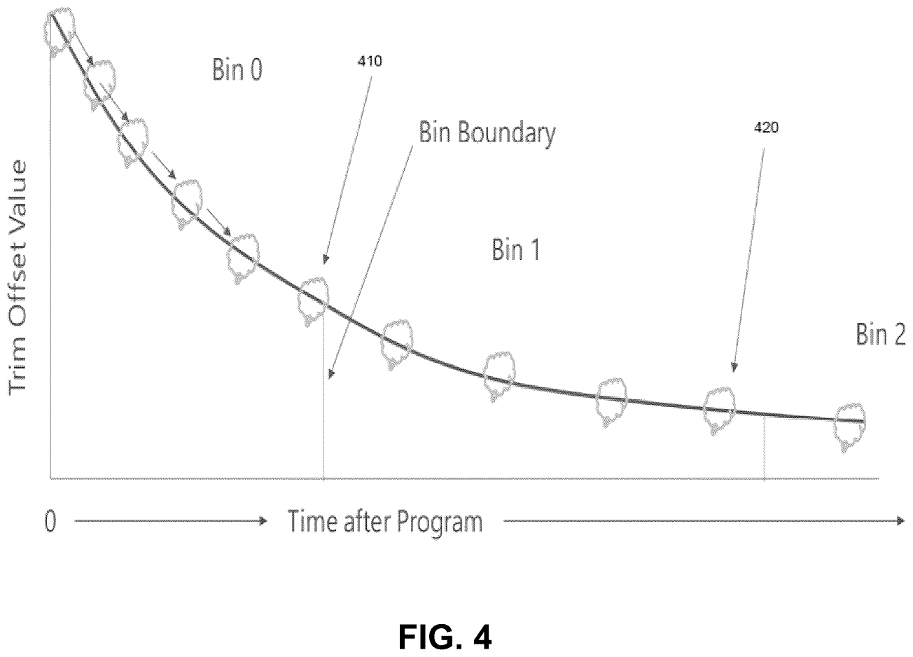

FIG. 3 schematically illustrates a set of predefined threshold voltage offset bins (bin 0 to TAP bin 9), in accordance with embodiments of the present disclosure. As schematically illustrated by FIG. 3, the threshold voltage offset graph can be subdivided into multiple threshold voltage offset bins, such that each bin corresponds to a predetermined range of threshold voltage offsets. While the illustrative example of FIG. 4 defines ten bins, in other implementations, various other numbers of bins can be employed (e.g., 64 bins). Based on a periodically performed calibration process, the memory sub-system controller associates each die of every block family with a threshold voltage offset bin, which defines a set of default threshold voltage offset values to be applied to the base voltage read level in order to perform read operations, as described in more detail herein below.

FIG. 4 schematically illustrates selecting block families for calibration, in accordance with embodiments of the present disclosure. As schematically illustrated by FIG. 4, the memory sub-system controller can limit the calibration operations to the oldest block family in each bin (e.g., block family 410 in bin 0 and block family 420 in bin 1), since it is the oldest block family that will, due to the slow charge loss, migrate to the next bin before any other block family of the current bin.

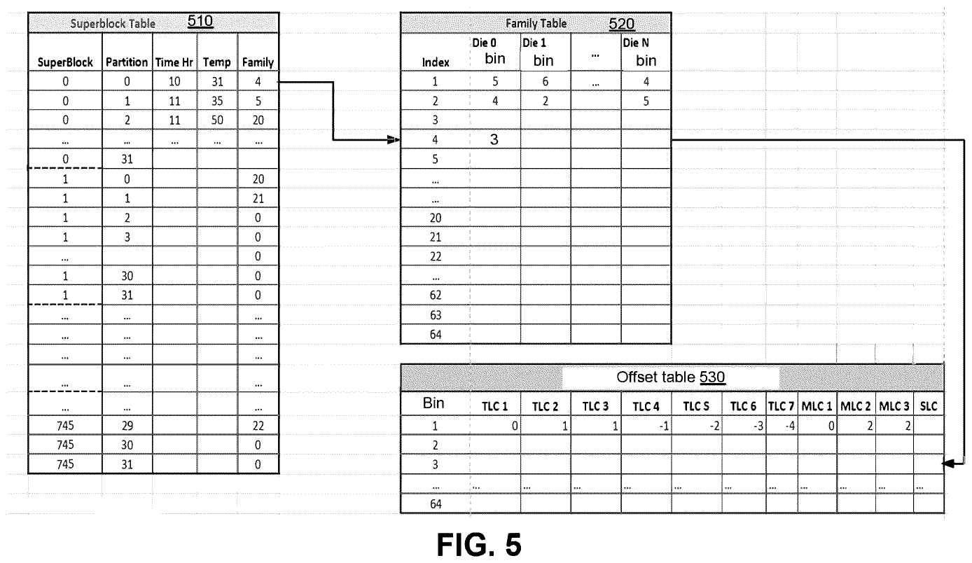

FIG. 5 schematically illustrates a BFEA data structure maintained by the memory sub-system controller for read level management, in accordance with embodiments of the present disclosure. The BFEA data structure 510 may include a plurality of entries identified by TAP bins 520 (e.g., TAP bins 1-7). Each of the TAP bins 520 corresponds to a time-after-programming (TAP) bin of a predetermined number of TAP bins, similar to the bins (e.g., bins 0-7) previously discussed. Each TAP bin (or entry) includes a plurality of default voltage offset values to be applied to base read levels during read operations. Each default voltage offset value of the plurality of default voltage offset values corresponds to a threshold voltage levels 530 (e.g., threshold voltage level 1-7), similar to L1-L7 previously discussed. The default voltage offset values refers to the voltage offsets used to mitigate the temporal voltage shift for programmed blocks grouped by block families. Accordingly, in view of block affiliation with a certain block family the default voltage offset values are applied to the base read levels in order to perform read operations.

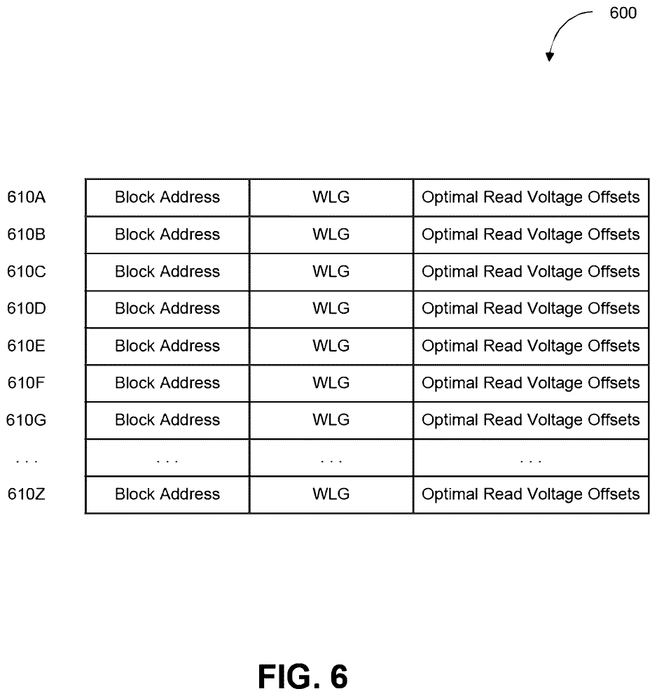

FIG. 6 schematically illustrates an error handling data structure maintained by the memory sub-system controller for BFEA using optimal read voltage offsets, in accordance with embodiments of the present disclosure. The error handling data structure 600 may include a plurality of entries (e.g., Entries 610A-Z). Each entry of the plurality of entries corresponds to a block address of a page that previously failed and underwent error handling (e.g., a previously failed page). Each entry includes a block address (of a previously failed page), a WLG (of the previously failed page), and a plurality of optimal read voltage offset values (for the previously failed page). In some embodiments, if a block family association to a specific TAP bin has changed, each entry including a block of the block family is removed from the error handling data structure. In some embodiments, the error handling data structure may be a predetermined size. In other words, a number of entries of the error handling data structure is fixed based on the predetermined size. Thus, if the number of entries of the error handling data structure reaches the predetermined size, an oldest entry (i.e., the earliest entry) of the error handling data structure is removed to accommodate a new entry.

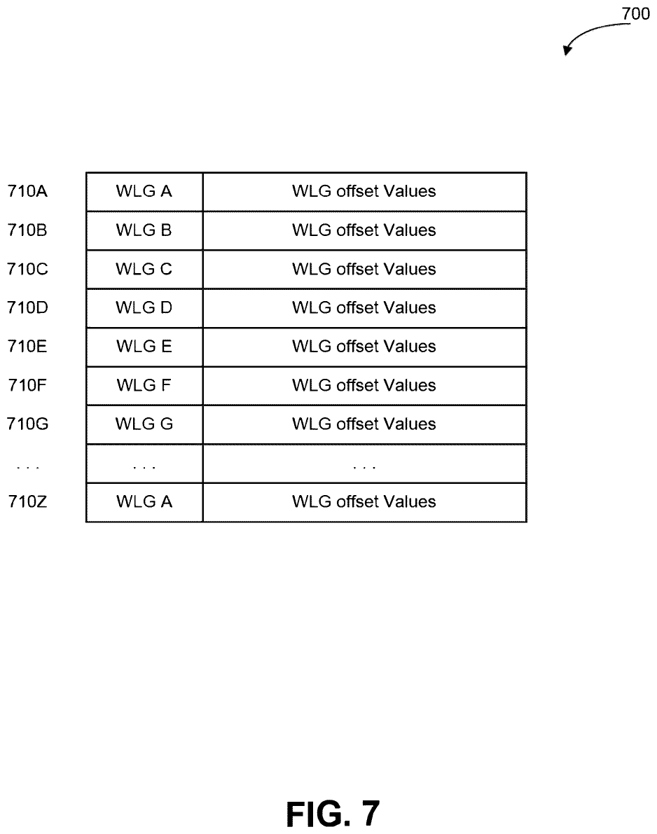

FIG. 7 schematically illustrates a WLG offset data structure maintained by the memory sub-system controller for BFEA using learned offset values, in accordance with embodiments of the present disclosure. The WLG data structure 700 may include a plurality of entries (e.g., Entries 710A-Z). Each entry includes a WLG (e.g., WLG A-Z) of the memory device (e.g., memory device 130 and/or 140) and a plurality of WLG offset values. As previously described, a WLG corresponds to adjacent wordlines each containing pages that share common operational characteristics due to their proximity. The plurality of WLG offset values for a WLG represents a differences between the WLG and a reference wordline group (e.g., WLG A), independent of temporal charge-loss characteristics. Each WLG offset value of the plurality of WLG offset values is predefined value generated during manufacturing based on characteristics of the WLG. Each WLG offset value of the plurality of WLG offset values corresponds to a threshold voltage levels (e.g., threshold voltage level 1-7), similar to threshold voltage levels 530 of FIG. 5.

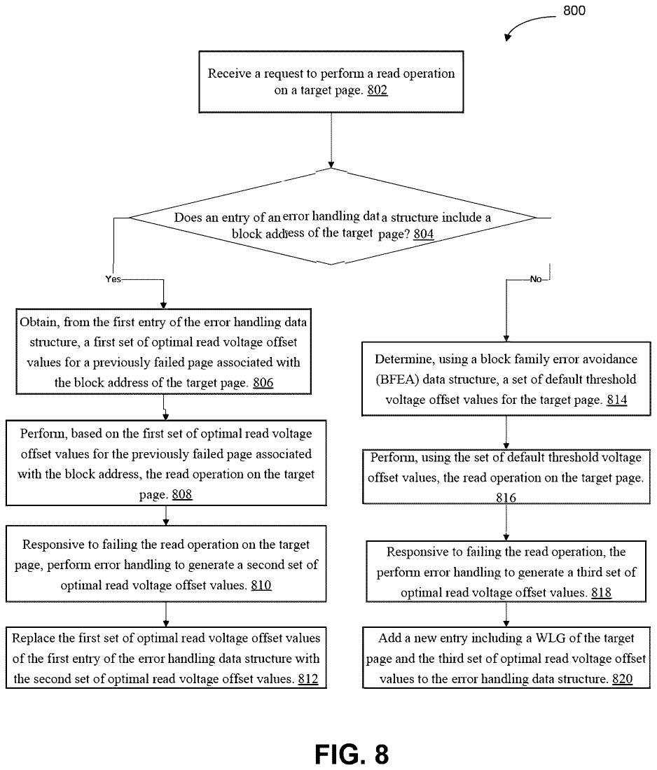

FIG. 8 is a flow diagram of an example method of block family error handling avoidance using optimal read voltage offsets, in accordance with some embodiments of the present disclosure. The method 800 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 800 is performed by the BFEA read level management component 113 of FIG. 1. Although shown in a particular sequence or order, unless otherwise specified, the order of the operations can be modified. Thus, the illustrated embodiments should be understood only as examples, and the illustrated operations can be performed in a different order, while some operations can be performed in parallel. Additionally, one or more operations can be omitted in some embodiments. Thus, not all illustrated operations are required in every embodiment, and other process flows are possible.

At operation 802, the processing logic receives, by a memory device, a request to perform a read operation on a target page. At operation 804, the processing logic determines whether an entry of an error handling data structure include a block address of the target page. As previously described, each entry of the error handling data structure corresponds to a block containing a previously failed page that underwent error handling. Thus, each entry may include a block address of a previously failed page, a WLG of the previously failed page, and a plurality of optimal read voltage offset values for the previously failed page.

If yes, at operation 806, the processing logic obtains, from a first entry of the error handling data structure, a first set of optimal read voltage offset values for a previously failed page associated with the block address of the target page. The first entry corresponds to an entry of the error handling data structure that included the block address of the target page.

At operation 808, the processing logic performs, based on the first set of optimal read voltage offset values for the previously failed page associated with the block address, the read operation on the target page. To perform the read operation on the target page using the first set of optimal read voltage offset values may include computing a difference between a first set of WLG offset values for a WLG of the previously failed page (from a first entry of the WLG offset data structure) and a second set of WLG offset values for a WLG of the target page (from a second entry of the WLG data structure) (e.g., a third set of WLG offset values or a plurality of delta WLG offset values). As previously described, each entry of the WLG data structure includes a WLG and a plurality of WLG offset values that represents a differences between a plurality of WLG offset values of the WLG and a plurality of WLG offset values of a WLG designated as a reference WLG. Accordingly, the read operation on the target page is performed by adding a sum of the third set of WLG offset values and the first set of optimal read voltage offset values to the base read levels.

At operation 810, responsive to failing the read operation on the target page, the processing logic performs error handling to generate a second set of optimal read voltage offset values. At operation 812, in response to successfully performing error handling, the processing logic replaces the first set of optimal read voltage offset values of the first entry of the error handling data structure with the second set of optimal read voltage offset values. In some embodiments, the WLG of the first entry of the error handling data structure may also be replaced with the WLG of target page.

If no, at operation 814, the processing logic determines, using a block family error avoidance (BFEA) data structure, a set of default threshold voltage offset values for the target page (i.e., corresponding to a first time after programming (TAP) bin assigned to a block family including a block containing the target page). Each entry of the BFEA data structure includes, for each TAP bin of the predetermined number of TAP bins, a plurality of default voltage offset values to be applied to base read levels for read operations. At operation 816, the processing logic performs, using the set of default threshold voltage offset values, the read operation on the target page. At operation 818, responsive to failing the read operation, the processing logic performs error handling to generate a third set of optimal read voltage offset values. At operation 820, in response to successfully performing error handling, the processing logic adds a new entry including a block address of the target page, a WLG of the target page and the third set of optimal read voltage offset values to the error handling data structure.

Depending on the embodiment, the processing logic may determine that a block of a block family association with a first time after programming (TAP) bin has transitioned to a second TAP bin. The processing logic identifies a second entry of the error handling data structure that includes a block address corresponding to the block and removes the second entry from the error handling data structure.

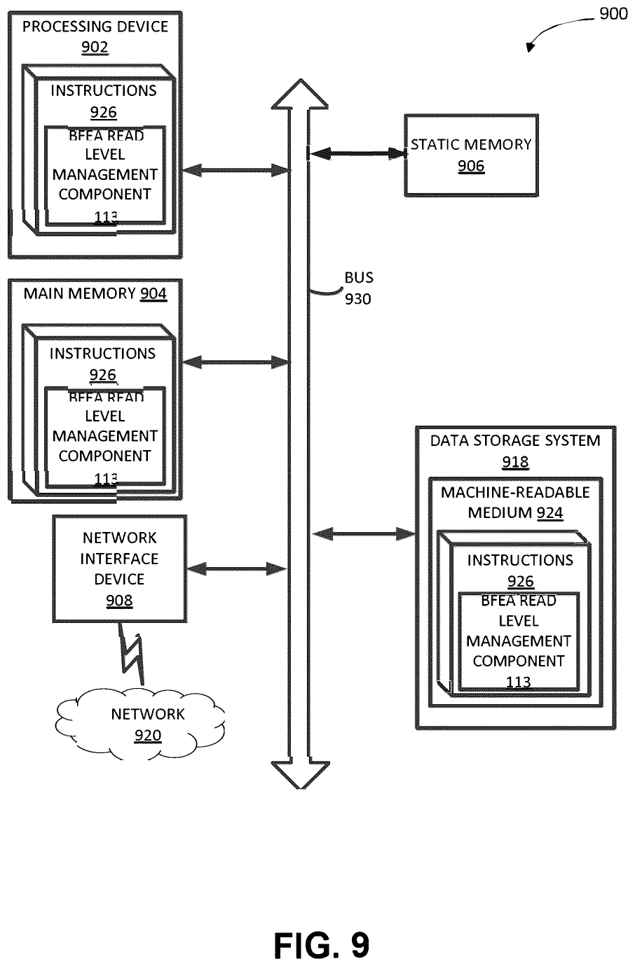

FIG. 9 illustrates an example machine of a computer system 900 within which a set of instructions, for causing the machine to perform any one or more of the methodologies discussed herein, can be executed. In some embodiments, the computer system 900 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the BFEA read level management component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 900 includes a processing device 902, a main memory 904 (e.g., read-only memory (ROM), flash memory, dynamic random access memory (DRAM) such as synchronous DRAM (SDRAM) or RDRAM, etc.), a static memory 906 (e.g., flash memory, static random access memory (SRAM), etc.), and a data storage system 918, which communicate with each other via a bus 930.

Processing device 902 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 902 can also be one or more special-purpose processing devices such as an application specific integrated circuit (ASIC), a field programmable gate array (FPGA), a digital signal processor (DSP), network processor, or the like. The processing device 902 is configured to execute instructions 926 for performing the operations and steps discussed herein. The computer system 900 can further include a network interface device 908 to communicate over the network 920.

The data storage system 918 can include a machine-readable storage medium 924 (also known as a computer-readable medium) on which is stored one or more sets of instructions 926 or software embodying any one or more of the methodologies or functions described herein. The instructions 926 can also reside, completely or at least partially, within the main memory 904 and/or within the processing device 902 during execution thereof by the computer system 900, the main memory 904 and the processing device 902 also constituting machine-readable storage media. The machine-readable storage medium 924, data storage system 918, and/or main memory 904 can correspond to the memory sub-system 110 of FIG. 1.

In one embodiment, the instructions 926 include instructions to implement functionality corresponding to a BFEA read level management component (e.g., the BFEA read level management component 113 of FIG. 1). While the machine-readable storage medium 924 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
receiving, by a processing device, a request to perform a read operation on a target page of a memory device;
determining whether an entry of an error handling data structure includes a block address of the target page;
responsive to determining that a first entry of the error handling data structure includes the block address of the target page, obtaining, from the first entry of the error handling data structure, a first set of optimal read voltage offset values for a previously failed page associated with the block address; and
performing, based on the first set of optimal read voltage offset values for the previously failed page associated with the block address, the read operation on the target page.

2. The method of claim 1, wherein performing, based on the first set of optimal read voltage offset values for the previously failed page associated with the block address, the read operation on the target page comprises:
obtaining, from a first entry of a wordline group (WLG) offset data structure, a first set of WLG offset values for a WLG of the previously failed page;
obtaining, from a second entry of the WLG data structure, a second set of WLG offset values for a WLG of the target page;
computing, based on the second set of WLG offset values and the first set of WLG offset values, a third set of WLG offset values; and
performing, using the third set of WLG offset values and the first set of optimal read voltage offset values, the read operation on the target page.

3. The method of claim 1, further comprising:
responsive to a failure of the read operation on the target page based on the first set of optimal read voltage offset values, performing an error handling operation to generate a second set of optimal read voltage offset values; and
replacing, in the first entry of the error handling data structure, the first set of optimal read voltage offset values with the second set of optimal read voltage offset values.

4. The method of claim 1, further comprising:
responsive to determining that each entry of the error handling data structure does not include the block address of the target page, determining, using a block family error avoidance (BFEA) data structure, a set of default threshold voltage offset values for the target page; and
performing, using the set of default threshold voltage offset values, the read operation on the target page.

5. The method of claim 4, wherein the set of default threshold voltage offset values correspond to a first time after programming (TAP) bin assigned to a block family including a block containing the target page.

6. The method of claim 4, further comprising:
responsive to a failure of the read operation on the target page using the set of default threshold voltage offset values, performing error handling to generate a third set of optimal read voltage offset values; and
adding a new entry including a WLG of the target page and the third set of optimal read voltage offset values to the error handling data structure.

7. The method of claim 1, further comprising:
responsive to determining that a block of a block family association with a first time after programming (TAP) bin has transitioned toa second TAP bin, identifying a second entry of the error handling data structure including a block address corresponding to the block; and
removing the second entry from the error handling data structure.

8. A system comprising:
a memory device; and
a processing device coupled to the memory device, the processing device to perform operations comprising:
receiving, by a processing device, a request to perform a read operation on a target page of a memory device; determining whether an entry of an error handling data structure includes a block address of the target page;
responsive to determining that a first entry of the error handling data structure includes the block address of the target page, obtaining, from the first entry of the error handling data structure, a first set of optimal read voltage offset values for a previously failed page associated with the block address; and
performing, based on the first set of optimal read voltage offset values for the previously failed page associated with the block address, the read operation on the target page.

9. The system of claim 8, wherein performing, based on the first set of optimal read voltage offset values for the previously failed page associated with the block address, the read operation on the target page comprises:
obtaining, from a first entry of a wordline group (WLG) offset data structure, a first set of WLG offset values for a WLG of the previously failed page;
obtaining, from a second entry of the WLG data structure, a second set of WLG offset values for a WLG of the target page;
computing, based on the second set of WLG offset values and the first set of WLG offset values, a third set of WLG offset values; and
performing, using the third set of WLG offset values and the first set of optimal read voltage offset values, the read operation on the target page.

10. The system of claim 8, further comprising:
responsive to a failure of the read operation on the target page based on the first set of optimal read voltage offset values, performing an error handling operation to generate a second set of optimal read voltage offset values; and
replacing, in the first entry of the error handling data structure, the first set of optimal read voltage offset values with the second set of optimal read voltage offset values.

11. The system of claim 8, wherein the processing device is to perform operations further comprising:
responsive to determining that each entry of the error handling data structure does not include the block address of the target page, determining, using a block family error avoidance (BFEA) data structure, a set of default threshold voltage offset values for the target page; and
performing, using the set of default threshold voltage offset values, the read operation on the target page.

12. The system of claim 11, wherein the set of default threshold voltage offset values correspond to a first time after programming (TAP) bin assigned to a block family including a block containing the target page.

13. The system of claim 11, wherein the processing device is to perform operations further comprising:
responsive to a failure of the read operation on the target page using the set of default threshold voltage offset values, performing error handling to generate a third set of optimal read voltage offset values; and
adding a new entry including a WLG of the target page and the third set of optimal read voltage offset values to the error handling data structure.

14. The system of claim 8, wherein the processing device is to perform operations further comprising:
responsive to determining that a block of a block family association with a first time after programming (TAP) bin has transitioned toa second TAP bin, identifying a second entry of the error handling data structure including a block address corresponding to the block; and
removing the second entry from the error handling data structure.

15. A non-transitory computer-readable storage medium comprising instructions that, when executed by a processing device, cause the processing device to perform operations comprising:
receiving, by a processing device, a request to perform a read operation on a target page of a memory device; determining whether an entry of an error handling data structure includes a block address of the target page;
responsive to determining that a first entry of the error handling data structure includes the block address of the target page, obtaining, from the first entry of the error handling data structure, a first set of optimal read voltage offset values for a previously failed page associated with the block address; and
performing, based on the first set of optimal read voltage offset values for the previously failed page associated with the block address, the read operation on the target page.

16. The non-transitory computer-readable storage medium of claim 15, wherein performing, based on the first set of optimal read voltage offset values for the previously failed page associated with the block address, the read operation on the target page comprises:
obtaining, from a first entry of a wordline group (WLG) offset data structure, a first set of WLG offset values for a WLG of the previously failed page;
obtaining, from a second entry of the WLG data structure, a second set of WLG offset values for a WLG of the target page;
computing, based on the second set of WLG offset values and the first set of WLG offset values, a third set of WLG offset values; and
performing, using the third set of WLG offset values and the first set of optimal read voltage offset values, the read operation on the target page.

17. The non-transitory computer-readable storage medium of claim 15, wherein the processing device is caused to perform operations further comprising:
responsive to a failure of the read operation on the target page based on the first set of optimal read voltage offset values, performing an error handling operation to generate a second set of optimal read voltage offset values; and
replacing, in the first entry of the error handling data structure, the first set of optimal read voltage offset values with the second set of optimal read voltage offset values.

18. The non-transitory computer-readable storage medium of claim 15, wherein the processing device is caused to perform operations further comprising:
responsive to determining that each entry of the error handling data structure does not include the block address of the target page, determining, using a block family error avoidance (BFEA) data structure, a set of default threshold voltage offset values for the target page; and
performing, using the set of default threshold voltage offset values, the read operation on the target page.

19. The non-transitory computer-readable storage medium of claim 18, wherein the processing device is caused to perform operations further comprising:
responsive to a failure of the read operation on the target page using the set of default threshold voltage offset values, performing error handling to generate a third set of optimal read voltage offset values; and
adding a new entry including a WLG of the target page and the third set of optimal read voltage offset values to the error handling data structure.

20. The non-transitory computer-readable storage medium of claim 15, wherein the processing device is caused to perform operations further comprising:
responsive to determining that a block of a block family association with a first time after programming (TAP) bin has transitioned to a second TAP bin, identifying a second entry of the error handling data structure including a block address corresponding to the block; and
removing the second entry from the error handling data structure.
